(19) United States
(12) Patent Application Publication
(10) Pub. No.: US 2026/0185668 A1
(43) Pub. Date: Jul. 2, 2026

(54) Cable Structure and Data Line

(71) Applicants: GUANGDONG OPSCO TECHNOLOGY CO., LTD, Dongguan (CN); DONGGUAN YIXUN ELECTRONICS CO., LTD, Dongguan (CN)

(72) Inventors: MINGJIAN LIU, Dongguan (CN); JIANZHONG ZHANG, Dongguan (CN); GENGSHENG ZHU, Dongguan (CN); ZHENLEI WU, Dongguan (CN); XIAOLIANG LI, Dongguan (CN)

(21) Appl. No.: 19/445,814

(22) Filed: Jan. 12, 2026

Related U.S. Application Data
(63) Continuation of application No. PCT/CN2023/107051, filed on Jul. 12, 2023.

(51) Int. Cl. F21S 4/26; F21Y 115/10; H01B 7/02; H01B 9/00; H01R 13/66; H01R 13/717; H01R 24/28; H01R 24/64; H02J 7/80; H10H 29/20; H10H 29/85; H10H 29/853; H10H 29/854

(52) U.S. Cl. CPC F21S 4/26; H01B 7/0266; H01B 9/003; H01R 13/665; H01R 13/7175; H01R 24/28; H01R 24/64; H02J 7/80; F21Y 2115/10; H02J 2207/30; H10H 29/20; H10H 29/8508; H10H 29/853; H10H 29/854; H10H 29/857

(57) ABSTRACT

The present application provides cable structure and a data line. The cable structure includes a power line and a communication line; in which a plurality of LED lamps are arranged on the power line at intervals; light-emitting directions of the plurality of LED lamps are the same as an extending direction of the power line; the LED lamp includes an insulating base, a communication chip, a light-emitting chip, and a conductive pin integrally embedded and molded with the insulating base; a protective adhesive is formed on the insulating base and covers the outside of the communication chip and the light-emitting chip; and the communication chip and the light-emitting chip are arranged in the insulating base and are electrically connected to the power line through the conductive pin.

### CROSS-REFERENCE TO RELATED APPLICATIONS

The application is a National Stage of International Application No. PCT/CN2023/107051, filed on Jul. 12, 2023, the entire contents of which are herein incorporated by reference.

### TECHNICAL FIELD

The present application relates to the technical field of data lines, and in particular, to a cable structure and a data line.

### BACKGROUND

With the rapid development of the electronics industry, electronic products have gradually become popular in people's daily lives. Data cables used for data transmission or charging of electronic products have become an indispensable part of our lives.

Existing data lines use LED lamps on the USB connectors and charging plugs at both ends of the cable structure to emit light, and then use optical fibers for light guiding, so that the entire cable structure emits light. However, this may easily cause the ends of the data line to be bright while the middle is dark, and the light-emitting form is single.

### SUMMARY OF THE INVENTION

In a first aspect, the present application provides a cable structure, including: a power line and a communication line;
in which a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp includes an insulating base, a communication chip, a light-emitting chip, and a conductive pin integrally embedded and molded with the insulating base; a protective adhesive is formed on the insulating base and covers the outside of the communication chip and the light-emitting chip; and
the communication chip and the light-emitting chip are arranged in the insulating base and are electrically connected to the power line through the conductive pin; the communication chip is configured to extract a control signal loaded on the power line and perform decoding work, and then extract data corresponding to an address of the communication chip, and output a driving signal that is recognized by the light-emitting chip.

In a second aspect, the present application further provides a cable structure, including: a power line and a communication line;
in which a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp includes an insulating base, a communication chip, a light-emitting chip, and conductive pin integrally embedded and molded with the insulating base; a protective adhesive is formed on the insulating base and covers the outside of the light-emitting chip; and
the communication chip and the light-emitting chip is arranged in the insulating base and is electrically connected to the power line through the conductive pin.

In a third aspect, the present application further provides a data line, including: a cable structure described above, and an adapter interface;
in which the cable structure has an input end for connecting to an external host or an external power source, and an output end for transmitting data or supplying power to an electronic device;
a USB connector of the adapter interface is connected to the input end;
a charging plug of the adapter interface is connected to the output end;
when the data line transmits data or supplies power to the electronic device, the communication chip is configured to analyze and process the control signal transmitted by a driving module through power line carrier and generate the driving signal that is recognized by the light-emitting chip, to control operation of the LED lamps of the cable structure.

### BRIEF DESCRIPTION OF THE DRAWINGS

In order to illustrate the technical solutions in the embodiments of the present application more clearly, the following will briefly introduce the drawings needed for describing the embodiments. Obviously, the drawings in the following description are some embodiments of the present application. For those of ordinary skill in the art, other drawings may be obtained based on these drawings without creative effort.

FIG. 1 is a schematic structural diagram of a data line provided by an embodiment of the present application.

FIG. 2 is an exploded view of the data line in FIG. 1.

FIG. 3 is a schematic structural diagram of the communication line in FIG. 2.

FIG. 4 is a schematic structural diagram showing the LED lamps connected to the power line in FIG. 2.

FIG. 5 is a schematic structural diagram of the LED lamp in FIG. 2.

FIG. 6 is an exploded view of the LED lamp in FIG. 2.

FIG. 7 is an exploded view of the USB connector in FIG. 2.

FIG. 8 is a schematic structural diagram of a data line provided by another embodiment of the present application.

FIG. 9 is an exploded view of the data line in FIG. 8.

FIG. 10 is a schematic structural diagram of a data line provided by another embodiment of the present application.

FIG. 11 is a schematic structural diagram of a data line provided by another embodiment of the present application.

### DETAILED DESCRIPTION

The technical solutions in the embodiments of the present application will be described clearly and completely below with reference to the accompanying drawings in the embodiments of the present application. Obviously, the described embodiments are a part of the embodiments of the present application, not all of them. Based on the embodiments in the present application, all other embodiments obtained by those of ordinary skill in the art without creative effort shall fall within the protection scope of the present application.

It should also be understood that the terminology used herein in the description of the present application is for the purpose of describing specific embodiments and is not intended to limit the present application. In the description of the present application, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, etc. indicate orientations or positional relationships based on the orientations or positional relationships shown in the drawings, are for convenience of describing the present application and simplifying the description, and do not indicate or imply that the referred device or element have a specific orientation, be constructed and operated in a specific orientation, and therefore cannot be construed as limiting the present application. Furthermore, the terms “first”, “second” are used for descriptive purposes and are not to be construed as indicating or implying relative importance or implicitly indicating the number of technical features indicated. Thus, features defined as “first” or “second” may explicitly or implicitly include one or more of the described features. In the description of the present application, “plurality” means two or more unless otherwise defined.

The present application provides a cable structure and a data line, which may use a communication chip to extract a control signal loaded on a power line and generate a driving signal for driving operation of a light-emitting chip, to achieve various lighting effects according to the control signal, such as dynamic flashing, multi-color lighting, or alternating lighting.

The present application provides a cable structure, including: a power line and a communication line;
in which a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp includes an insulating base, a communication chip, a light-emitting chip, and a conductive pin integrally embedded and molded with the insulating base; a protective adhesive is formed on the insulating base and covers the outside of the communication chip and the light-emitting chip; and
the communication chip and the light-emitting chip are arranged in the insulating base and are electrically connected to the power line through the conductive pin; the communication chip is configured to extract a control signal loaded on the power line and perform decoding work, and then extract data corresponding to an address of the communication chip, and output a driving signal that is recognized by the light-emitting chip.

In some embodiments, the power line includes a positive line and a negative line;
the positive line is connected to a VDD pin of the communication chip; and
the negative line is connected to a GND pin of the communication chip.

In some embodiments, a plurality of accommodating holes are arranged between the positive line and the negative line;
the plurality of accommodating holes are arranged sequentially along a length direction of the positive line and the negative line; and
the plurality of LED lamps are correspondingly accommodated in the plurality of accommodating holes.

In some embodiments, the insulating base is provided with a first conductive groove and a second conductive groove;
the first conductive groove and the second conductive groove are respectively arranged on two sides of the insulating base; and
the positive line and the negative line correspondingly pass through the first conductive groove and the second conductive groove.

In some embodiments, the conductive pin includes a GND pin and a VDD pin;
the communication chip is arranged on the GND pin and is electrically connected to the GND pin and the VDD pin; and
the light-emitting chip is arranged on the VDD pin and is electrically connected to the VDD pin and the communication chip.

In some embodiments, the GND pin has a first die-bonding portion and a first soldering portion;
the VDD pin has a second die-bonding portion and a second soldering portion;
the communication chip is fixed on the first die-bonding portion;
the light-emitting chip is fixed on the second die-bonding portion;
the first soldering portion is soldered to the positive line; and
the second soldering portion is soldered to the negative line.

In some embodiments, the second die-bonding portion has a first notch;
the first die-bonding portion has a first connection surface and a second connection surface which are connected to each other and arranged at intervals; and
the first connection surface and the second connection surface are arranged in the first notch.

In some embodiments, the cable structure further includes a light-homogenizing tube;
the light-homogenizing tube is arranged on the outside of the power line and the LED lamps; and
the communication line is wound on the outside of the light-homogenizing tube and forms a light-transmitting hole.

In some embodiments, the communication line includes a plurality of data transmission lines; and
the plurality of data transmission lines are cross-woven with each other to form an entire outer layer of the light-homogenizing tube.

The present application further provides a cable structure, including: a power line and a communication line;
in which a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp includes an insulating base, a communication chip, a light-emitting chip, and conductive pin integrally embedded and molded with the insulating base; a protective adhesive is formed on the insulating base and covers the outside of the light-emitting chip; and
the communication chip and the light-emitting chip is arranged in the insulating base and is electrically connected to the power line through the conductive pin.

In some embodiments, the cable structure further includes a data transmission line; and
the data transmission line is connected to the communication chip through the conductive pin and is configured to drive the light-emitting chip to emit light.

In some embodiments, the cable structure further includes a light-homogenizing tube;
the power line and/or the communication line are arranged inside the light-homogenizing tube; or
the power line, the communication line, and/or a data transmission line of the cable structure are arranged inside the light-homogenizing tube.

In some embodiments, the communication line and the power line are twisted together to form a wire bundle; and
an outer layer made of a light-homogenizing material is arranged on the outside of the wire bundle.

In some embodiments, the outer layer includes a light-homogenizing tube;
the light-homogenizing tube is sleeved on the outside of the wire bundle; or
the light-homogenizing tube is coated on the outside of the wire bundle by an injection molding process.

In some embodiments, the outer layer includes a braided sleeve; and
the braided sleeve is coated on the outside of the wire bundle.

In some embodiments, the cable structure further includes a spacer fabric made of an opaque material; and
the spacer fabric is coated on the outside of the outer layer, light on the outer layer pass through gaps of the spacer fabric.

In some embodiments, the spacer fabric includes a plurality of opaque braided lines; and
the plurality of braided lines are cross-woven with each other and are coated on the outside of the light-homogenizing tube.

In some embodiments, an outer layer made of a light-homogenizing material is arranged on the outside of the power line; and
the communication lines are cross-woven with each other and are coated on the outside of the outer layer.

The present application further provides a data line, including: a cable structure described above, and an adapter interface;
in which the cable structure has an input end for connecting to an external host or an external power source, and an output end for transmitting data or supplying power to an electronic device;
a USB connector of the adapter interface is connected to the input end;
a charging plug of the adapter interface is connected to the output end;
when the data line transmits data or supplies power to the electronic device, the communication chip is configured to analyze and process the control signal transmitted by a driving module through power line carrier and generate the driving signal that is recognized by the light-emitting chip, to control operation of the LED lamps of the cable structure.

In some embodiments, the adapter interface includes: an interface body and a circuit board;
a cavity structure is arranged on the interface body; and
the circuit board is accommodated in the cavity structure and is provided with a driving module for encoding a control signal, the control signal is transmitted externally through power line carrier, to control LED lamps of a cable structure connected to the interface body to emit light.

In some embodiments, the adapter interface includes a USB connector for inputting power or transmitting data, and at least one charging plug for connecting to an electronic device;
the circuit board is arranged in the USB connector; and
the USB connector and the charging plug are respectively connected to two ends of the cable structure.

In some embodiments, the charging plug includes at least one of a Lightning plug, a USB TYPE-C plug, and a Micro USB plug.

The present application designs a cable structure and a data line; the cable structure includes a power line, a communication line and a plurality of LED lamps; the LED lamp includes an insulating base, a communication chip, a light-emitting chip, and conductive pin integrally embedded and molded with the insulating base. The communication chip and the light-emitting chip are arranged on the insulating base and are electrically connected to the power line through the conductive pin. The communication line is wrapped on the outside of the power line or the power line is wrapped on the outside of the communication line. So that the communication chip may extract a control signal loaded on the power line, perform decoding, then extract data corresponding to the address of the communication chip, output a driving signal that may be recognized by the light-emitting chip, for driving operation of the light-emitting chip, thereby determining the lighting method according to the control signal and achieving various lighting effects, such as dynamic flashing, multi-color lighting, or alternating lighting. In addition, since the light-emitting directions of the plurality of LED lamps are the same as the extending direction of the power line, the brightness of the optical path in the middle area of the cable structure is consistent with the brightness of the optical paths at both ends, resulting in better lighting effects for the cable structure.

It should be understood that the above description and the following detailed description are exemplary and explanatory and are not restrictive of the present application.

Hereinafter, some embodiments of the present application will be described in detail with reference to the accompanying drawings. The embodiments and features in the embodiments may be combined with each other without conflict.

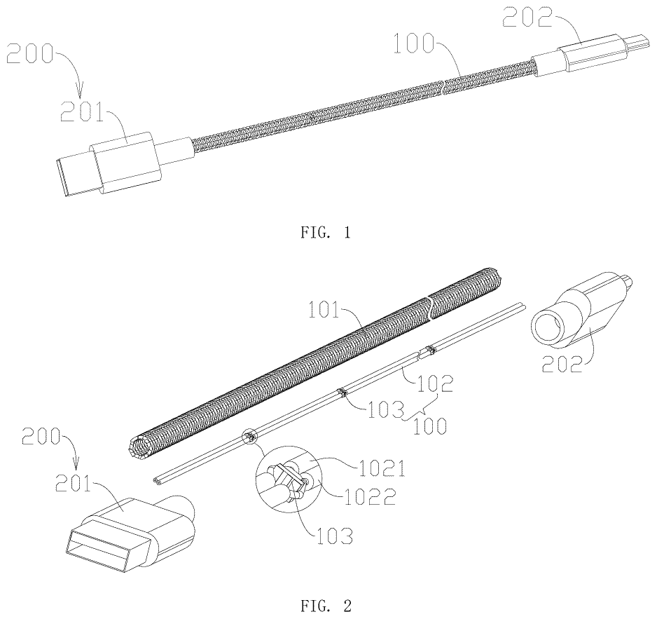

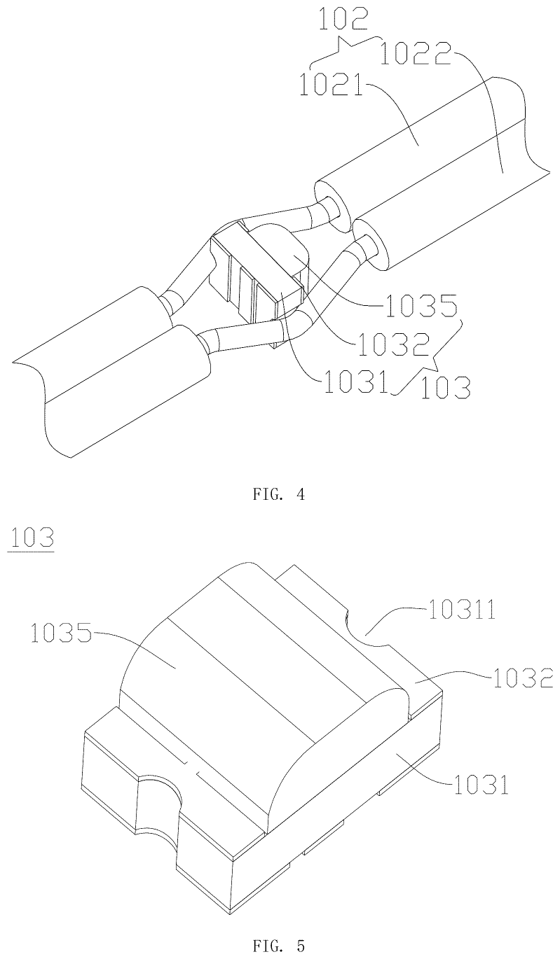

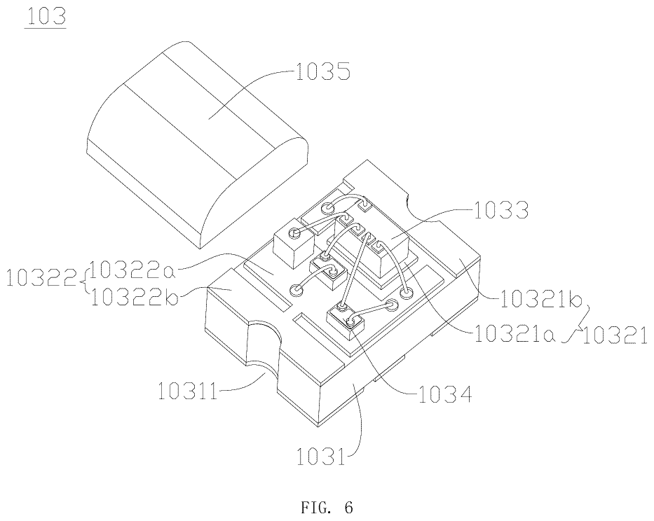

As shown in FIGS. 1 to 7, the present application provides a data line, including a cable structure 100 and an adapter interface 200. The adapter interface 200 is provided with a driving module and is connected to the cable structure 100, and is configured to encode a control signal from an external host or an integrator built into the adapter interface 200, so that the control signal may be transmitted through the cable structure 100 through power line carrier.

In this embodiment, a plurality of LED lamps 103 are arranged on the cable structure 100 at intervals; the LED lamp 103 is provided with a communication chip 1033; the communication chip 1033 is connected to the adapter interface 200 through the cable structure 100, so that the communication chip 1033 may extract a control signal loaded on the cable structure 100, perform decoding on the control signal, extract address data corresponding to the address of the communication chip 103, and then control the communication chip 1033 to output corresponding effect changes according to the address data, to drive the operation of the LED lamp 103. It does not require a separate signal control cable, reduces resource usage, and may determine the lighting method of the LED lamp 103 according to the control signal, achieving various lighting effects, such as dynamic flashing, multi-color lighting, or alternating lighting. At the same time, the control signal is carried on the power line of the cable structure 100, allowing both signal transmission and power supply to work normally simultaneously, greatly simplifying the circuit structure of the data line. The design is ingenious, cost-effective, and practical.

In some embodiments, the driving module uses its internal oscillator to perform high-low oscillation on the received control signal and loads it onto the power line connected to the positive power supply for transmission, thereby enabling the transmission of the control signal. That is, the data information processed and oscillated by the oscillator may be transmitted to the LED lamp 103 through the power line. The communication chip may then extract and decode the carrier wave on the power line, i.e., decode the oscillated data information. When the decoding of the oscillated data information is completed, it is buffered at this level and then output to an RGB port to turn on or off the LED lamp 103, thereby achieving various lighting effects, such as dynamic flashing, multi-color lighting, or alternating lighting.

In some embodiments, the cable structure 100 includes a power line 102. A plurality of LED lamps 103 are arranged on the power line 102 at intervals and are electrically connected to the power line 102. The light-emitting direction of each LED lamp 103 is the same as the extending direction of the power line 102, so that all LED lamps 103 may emit light in the same direction as the power line 102, to enhance the visual effect of the cable structure 100 during use.

Since the plurality of LED lamps 103 are distributed on the power line 102 at intervals, the brightness of the optical path in the middle area of the cable structure 100 is consistent with the brightness of the optical paths at both ends. At the same time, the communication chip 1033 inside the LED lamp 103 may extract the control signal loaded on the power line and perform decoding, then extract data corresponding to the address of the communication chip, and output a driving signal that may be recognized by the LED lamp 103, thereby determining the lighting method of the LED lamp 103 and achieving various lighting effects, such as dynamic flashing, multi-color lighting, or alternating lighting, making the visual effect of the cable structure 100 during use more dazzling.

In this embodiment, the cable structure 100 further includes a communication line 101. The communication line 101 is wrapped on the outside of the power line 102, so that light emitted by the LED lamps 103 may pass through the communication line 101 to emit outward. Alternatively, the power line 102 is wrapped on the outside of the communication line 101. Alternatively, the power line 102 and the communication line 101 are arranged side by side, so that the LED lamps 103 may directly emit light outward, making the cable structure 100 more beautiful during use and satisfying people's pursuit of a sense of ritual and aesthetics in life.

In some embodiments, the LED lamp 103 includes an insulating base 1031, a communication chip 1033, a conductive pin 1032 and a light-emitting chip 1034. The conductive pin 1032 are integrally embedded and molded with the insulating base 1031. A protective adhesive 1035 is formed on the insulating base 1031, covering the outside of the communication chip 1033 and the light-emitting chip 1034 and facing the extending direction of the power line 102. In this embodiment, the communication chip 1033 and the light-emitting chip 1034 are arranged on the insulating base 1031 and are electrically connected to the power line 102 through the conductive pin 1033, so that the communication chip 1033 may extract a control signal loaded on the power line, perform decoding, then extract data corresponding to the address of the communication chip, and output a driving signal that may be recognized by the light-emitting chip 1034, to drive the operation of the LED lamp 103, so that the LED lamp 103 has corresponding effect changes.

After adopting the above technical solution, not only is a separate signal control cable not required, reducing resource usage, but also the lighting method of the LED lamp 103 may be determined according to the control signal, achieving various lighting effects, such as dynamic flashing, multi-color lighting, or alternating lighting. Moreover, by carrying the control signal on the power line of the cable structure 100, both signal transmission and power supply may work normally simultaneously, greatly simplifying the circuit structure of the data line. The design is ingenious, cost-effective, and practical.

In some embodiments, the power line 102 includes a positive line 1021 connected to the VDD pin of the communication chip 1033. The input end of the communication chip 1033 is connected to the output end of the positive line 1021, and the output end of the communication chip 1033 is connected to the light-emitting chip 1034 for controlling the light-emitting chip 1034 to emit light.

In some embodiments, the power line 102 further includes a negative line 1022 connected to the GND pin of the communication chip 1033. The voltage level of the negative line 1022 is lower than that of the positive line 1021. The LED lamp 103 is electrically connected to the positive line 1021 and the negative line 1022 through the conductive pin 1032.

In some embodiments, the positive line 1021 may be a positive power line, and the negative line 1022 may be a ground line or a negative power line. The communication chip 1033 is connected to the positive line 1021 through the conductive pin 1032 to extract the carrier wave on the positive line 1021, i.e., the oscillated data information, then decode the carrier wave and output a driving signal that may be recognized by the light-emitting chip 1034, to drive the operation of the LED lamp 103, so that the LED lamp 103 has corresponding effect changes.

In some embodiments, a plurality of accommodating holes are arranged between the positive line 1021 and the negative line 1022. The plurality of accommodating holes are arranged sequentially along the length direction of the positive line 1021 and the negative line 1022. The plurality of LED lamps 103 are correspondingly accommodated in the plurality of accommodating holes, so that the cable structure 100 may emit light during charging or data transmission. At the same time, the light emitted by the LED lamps 103 is consistent with the extending direction of the cable structure 100, ensuring that the brightness of the optical paths at both ends of the cable structure is consistent with that in the middle area. At the same time, the communication chip 1033 inside the LED lamp 103 may achieve various lighting effects for the LED lamp 103.

In some embodiments, the insulating base 1031 is provided with a groove structure 10311, namely a first conductive groove and a second conductive groove. The first conductive groove and the second conductive groove are symmetrically arranged on two sides of the insulating base 1031. The positive line 1021 and the negative line 1022 correspondingly pass through the first conductive groove and the second conductive groove. The positive line 1021 and the negative line 1022 are correspondingly connected to the conductive pin 1032 on the LED lamp 103 to realize the electrical connection between the communication chip 1033 and the light-emitting chip 1034 and the positive line 1021 and the negative line 1022.

In some embodiments, the conductive pin 1032 include a GND pin 10321 and a VDD pin 10322. The communication chip 1033 is arranged on the GND pin 10321 and is electrically connected to the GND pin 10321 and the VDD pin 10322. The light-emitting chip 1034 is arranged on the VDD pin 10322 and is electrically connected to the VDD pin 10322 and the communication chip 1034.

In some embodiments, the GND pin 10321 has a first die-bonding portion 10321a and a first soldering portion 10321b connected to 10321a. The VDD pin 10322 has a second die-bonding portion 10322a and a second soldering portion 10322b connected to the second die-bonding portion 10322a. The communication chip 1033 is fixed on the first die-bonding portion 10321a. The light-emitting chip 1034 is fixed on the second die-bonding portion 10322a. The first soldering portion 10321b is soldered to the positive line 1021. The second soldering portion 10322b is soldered to the negative line 1022. The protective adhesive 1035 faces the extending direction of the positive line 1021 and the negative line 1022.

In some embodiments, the second die-bonding portion 10321a has a first notch. The first die-bonding portion 10322a has a first connection surface and a second connection surface which are connected to each other and arranged at intervals. The first connection surface and the second connection surface are arranged in the first notch. The first connection surface is arranged on the outside of the first notch. The communication chip 1033 is fixed on the second connection surface. The communication chip 1033 is electrically connected to the first connection surface through bonding wires. The light-emitting chip 1034 is electrically connected to the communication chip 1033 and the second die-bonding portion 10322a through bonding wires. By adopting the above technical solution, the connection between the protective adhesive 1035 and the insulating base 1031 may be more stable, and the stress generated when the protective adhesive 1035 expands due to heat may be released.

In this embodiment, the light-emitting chip 1034 includes a blue chip, a red chip, and a green chip. The blue chip, red chip, and green chip are arranged on the second die-bonding portion 10322a at intervals. The blue chip and the green chip are electrically connected to the second die-bonding portion 10322a through bonding wires. The bottom of the red chip is directly electrically connected to the second die-bonding portion 10322a.

In some embodiments, the cable structure 100 further includes a light-homogenizing tube. The light-homogenizing tube is arranged on the outside of the power line 102 and the LED lamps 103. The communication line 101 is wound on the outside of the light-homogenizing tube and forms a light-transmitting hole, so that light emitted by the LED lamps 103 may pass through the light-transmitting hole. The light-homogenizing tube may cooperate with the LED lamps 103, resulting in good lighting effect of the LED lamps 103, avoiding glare, and achieving full-area lighting, improving the overall lighting effect of the cable structure 100.

In some embodiments, the transmission line 101 includes a plurality of data transmission lines 1011. The plurality of data transmission lines 1011 are cross-woven with each other to form the entire outer layer of the light-homogenizing tube. The outer layer is coated on the outside of the light-homogenizing tube.

In some embodiments, the number of data transmission lines 1011 is four. The four data transmission lines 1011 are cross-woven and form a hollow structure 1012 for placing the light-homogenizing tube, so that the light-homogenizing tube and the power line 102 and LED lamps 103 inside it may be accommodated in the hollow structure 1012. The weaving method may enhance the strength of the cable structure 100, preventing the copper wires inside the cable structure 100 from breaking when bent.

In some embodiments, the adapter interface 200 includes an interface body 2011 and a circuit board 2012. A cavity structure is arranged on the interface body 2011. The circuit board 2012 is accommodated in the cavity structure. The driving module is arranged on the circuit board 2012 and is configured to encode a control signal, so that the control signal may be transmitted externally through power line carrier, to control the LED lamps 103 of the cable structure 100 connected to the interface body 2011.

In some embodiments, the control signal may be input to the adapter interface 201 by an external host. In some other embodiments, the control signal may be stored in an integrator on the circuit board 2012. When the data line transmits data or charges, the control signal may control the LED lamps 103 of the cable structure 100 through power line carrier, enabling the LED lamps 103 to achieve various lighting effects. At the same time, it may also prevent the situation where the ends of the cable structure 100 are brighter while the middle is darker.

In some embodiments, the adapter interface 200 includes a USB connector 201 for inputting power or transmitting data and at least one charging plug 202 for connecting to an electronic device. The circuit board 2012 is arranged in the USB connector 201. The USB connector 201 and the charging plug 202 are respectively connected to two ends of the cable structure 100.

In some embodiments, the charging plug 202 includes at least one of a Lightning plug, a USB TYPE-C plug, and a Micro USB plug.

According to the second aspect of the present application, as shown in FIGS. 1 to 11, a cable structure 100 is further provided. The cable structure 100 includes a power line 102 and a communication line 101; a plurality of LED lamps 103 are arranged on the power line 102 at intervals; the light-emitting directions of the plurality of LED lamps 103 are the same as the extending direction of the power line 102. The communication line 101 is wrapped on the outside of the power line 102, so that light emitted by the LED lamps 103 may pass through the communication line 101 to emit outward. Alternatively, the power line is wrapped on the outside of the communication line 101, so that the LED lamps 103 may directly emit light outward. Alternatively, the power line 102 and the communication line 101 are arranged side by side, so that the LED lamps 103 may directly emit light outward, making the cable structure 100 more beautiful during use and satisfying people's pursuit of a sense of ritual and aesthetics in life.

In this embodiment, the LED lamp 103 includes an insulating base 1031, a communication chip 1033, a conductive pin 1032 and a light-emitting chip 1034. The conductive pin 1032 are integrally embedded and molded with the insulating base 1031. A protective adhesive 1035 is formed on the insulating base 1031, covering the outside of the communication chip 1033 and the light-emitting chip 1034 and facing the extending direction of the power line 102. The communication chip 1033 and the light-emitting chip 1034 are arranged on the insulating base 1031 and are electrically connected to the power line 102 through the conductive pin 1033. The communication chip 1033 may extract a control signal loaded on the power line, perform decoding, then extract data corresponding to the address of the communication chip, and output a driving signal that may be recognized by the light-emitting chip 1034. Or, the communication chip 1033 may receive the control signal through a separately arranged data transmission line, to drive the operation of the LED lamp 103, so that the LED lamp 103 has corresponding effect changes.

It should be noted that the number of power lines 102 and communication lines 101 may be multiple. The power line 102 may share the positive line 1021 and the negative line 1022 in the communication line 101. The power line 102 may also be independent of the positive line 1021 and the negative line 1022 in the communication line 101. That is, the number of communication lines 101 may be two, four, or more, which is not limited in the present application.

Similarly, the communication chip 1033 may extract a control signal loaded on the power line and perform decoding to generate a driving signal that may be recognized by the light-emitting chip 1034. Or, the communication chip 1033 may also receive the control signal through a separately arranged data transmission line, which is not limited in the present application.

After adopting the above technical solution, the lighting method of the LED lamp 103 may be determined according to the control signal received by the light-emitting chip 1034, achieving various lighting effects, such as dynamic flashing, multi-color lighting, or alternating lighting. In addition, by carrying the control signal on the power line of the cable structure 100, both signal transmission and power supply may work normally simultaneously, greatly simplifying the circuit structure of the data line. The design is ingenious, cost-effective, and practical.

In some embodiments, the cable structure 100 further includes a data transmission line. The data transmission line is connected to the communication chip 1033 through the conductive pin 1032 and is configured to drive the light-emitting chip 1034 to emit light, to achieve various lighting effects, such as dynamic flashing, multi-color lighting, or alternating lighting, making the visual effect of the cable structure 100 during use more dazzling.

In some embodiments, the cable structure further includes a light-homogenizing tube 300. The communication line 101 and/or the power line 102 are arranged inside the light-homogenizing tube 300. The light-homogenizing tube 300 may cooperate with the LED lamps 103, resulting in good lighting effect of the LED lamps 103, avoiding glare, and achieving full-area lighting, improving the overall lighting effect of the cable structure 100.

In some embodiments, the communication line 101 and the power line 102 may be arranged inside the light-homogenizing tube 300 at the same time. In some other embodiments, the power line 102 is arranged inside the light-homogenizing tube 300, and the communication line 101 is arranged on the outside of the light-homogenizing tube 300. The light-homogenizing tube is used to cooperate with the LED lamps 103 arranged on the power line 102 at intervals, resulting in good lighting effect of the LED lamps 103, avoiding glare, and achieving full-area lighting, improving the overall lighting effect of the cable structure 100.

Furthermore, when the cable structure further includes the aforementioned data transmission line, the data transmission line and the power line 102 may be arranged inside the light-homogenizing tube at the same time, or the data transmission line and the communication line 101 may be arranged inside the light-homogenizing tube at the same time, which is not limited in the present application.

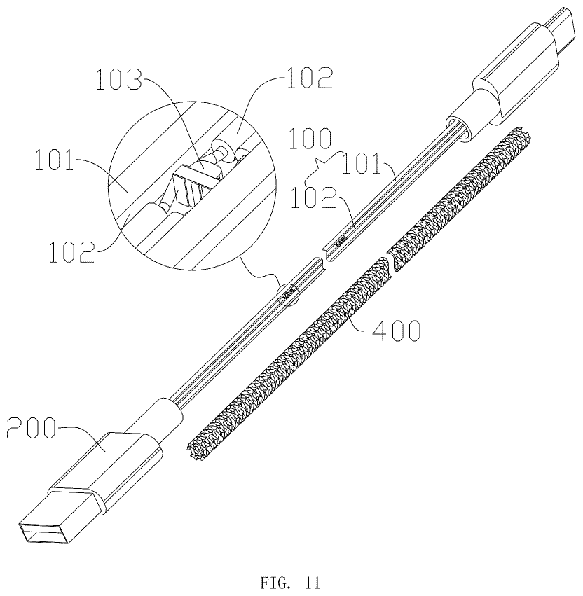

In some embodiments, as shown in FIGS. 8 and 11, the communication line 101 and the power line 102 are twisted together to form a wire bundle. An outer layer made of a light-homogenizing material is arranged on the outside of the wire bundle, so that the LED lamps 103 arranged on the power line 102 at intervals may cooperate with the outer layer, avoiding glare, and also achieving full-area lighting, improving the overall lighting effect of the cable structure 100.

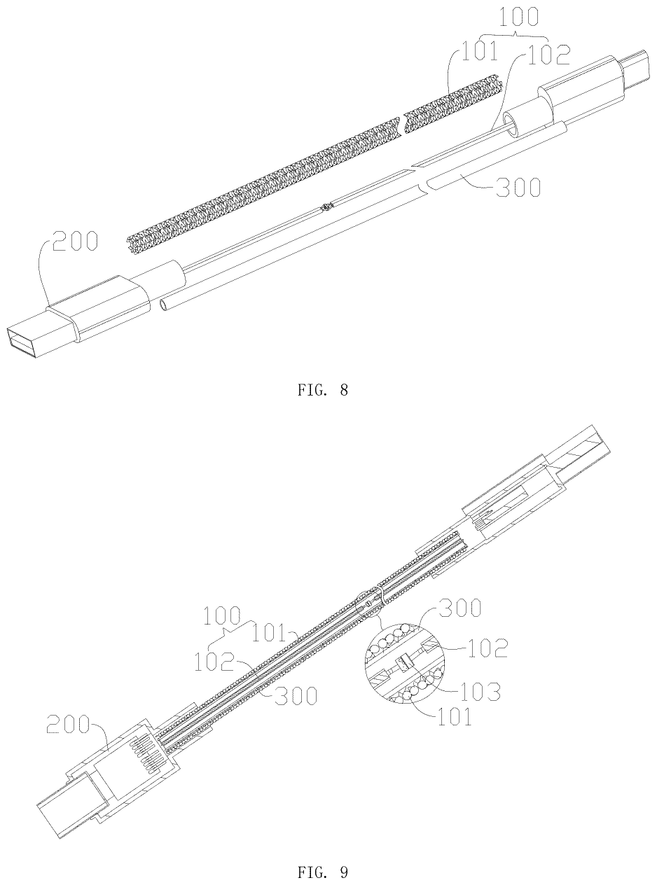

In some embodiments, as shown in FIGS. 8 and 9, the outer layer includes a light-homogenizing tube 300. The light-homogenizing tube is sleeved on the outside of the wire bundle. Or, the light-homogenizing tube 300 is coated on the outside of the wire bundle by an injection molding process.

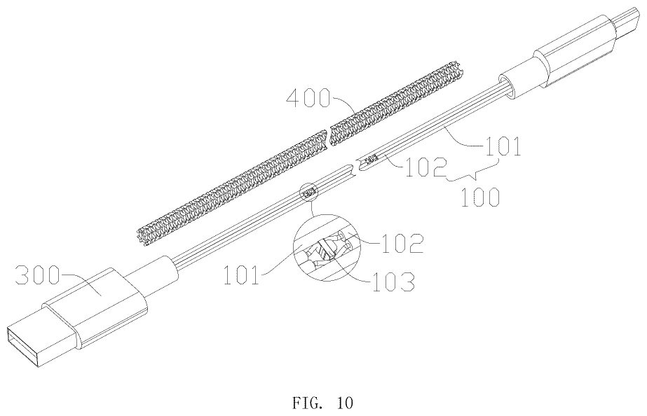

In some embodiments, as shown in FIGS. 10 and 11, the outer layer includes a braided sleeve 400. The braided sleeve 400 is coated on the outside of the wire bundle.

In some embodiments, the cable structure 100 further includes a spacer fabric made of an opaque material. The spacer fabric is coated on the outside of the outer layer, so that light on the outer layer may pass through gaps of the spacer fabric. The spacer fabric may effectively prevent shadows on the outer layer due to the opacity of the power line 102, making the lighting effect of the cable structure 100 better.

In some embodiments, the spacer fabric includes a plurality of opaque braided lines. The plurality of braided lines are cross-woven with each other and are coated on the outside of the light-homogenizing tube 300. The braided lines may be insulating or non-insulating materials, which is not limited in the present application.

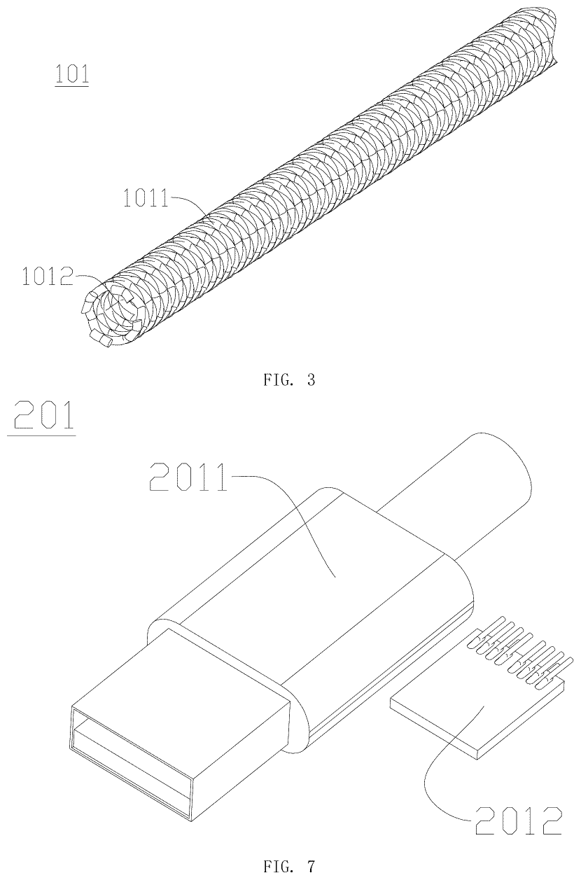

In some embodiments, as shown in FIGS. 1 and 2, an outer layer made of a light-homogenizing material is arranged on the outside of the power line 102. The communication lines 102 are cross-woven with each other and are coated on the outside of the light-Homogenizing tube.

In some embodiments, as shown in FIGS. 8 and 9, the number of power lines 102 may be two, and the number of communication lines 101 may be two. The two power lines 102 are arranged inside the light-homogenizing tube 300 for supplying power to the LED lamps 103 and charging the electronic device. The two communication lines 101 are cross-woven with each other and are coated on the outside of the light-homogenizing tube 300. Or, the number of power lines 102 is four or five. Two of the power lines 102 are arranged inside the light-homogenizing tube 300 for supplying power to the LED lamps 103. The two communication lines 101 and the remaining two or three power lines 102 are cross-woven with each other and are coated on the outside of the light-homogenizing tube 300.

In some embodiments, as shown in FIG. 10, the number of power lines 102 may be two, and the number of communication lines 101 is two. That is, the power lines 102 may not only be used to supply power to the LED lamps 103 but also charge the electronic device. The two power lines 102 and the two communication lines 101 are arranged inside the braided sleeve 400.

In some embodiments, as shown in FIG. 11, the number of power lines 102 may be four, and the number of communication lines 101 is two. Two of the power lines 102 may be used to supply power to the LED lamps 103, and the other two power lines 102 are used to charge the electronic device. The four power lines 102 and the communication lines 101 are arranged inside the braided sleeve 400.

Since the plurality of LED lamps 103 are distributed on the power line 102 at intervals, the brightness of the optical path in the middle area of the cable structure 100 is consistent with the brightness of the optical paths at both ends. The driving signal may also be received through the data transmission line or power line carrier transmission to determine the lighting method of the LED lamp 103, achieving various lighting effects, such as dynamic flashing, multi-color lighting, or alternating lighting, making the visual effect of the cable structure 100 during use more dazzling.

In some embodiments, the LED lamp 103 includes an insulating base 1031, a communication chip 1033, a conductive pin 1032 and a light-emitting chip 1034. The conductive pin 1032 are integrally embedded and molded with the insulating base 1031. A protective adhesive 1035 is formed on the insulating base 1031, covering the outside of the communication chip 1033 and the light-emitting chip 1034 and facing the extending direction of the power line 102. In this embodiment, the communication chip 1033 and the light-emitting chip 1034 are arranged on the insulating base 1031 and are electrically connected to the power line 102 through the conductive pin 1033, so that the communication chip 1033 may extract a control signal loaded on the power line, perform decoding, then extract data corresponding to the address of the communication chip, and output a driving signal that may be recognized by the light-emitting chip 1034, to drive the operation of the LED lamp 103, so that the LED lamp 103 has corresponding effect changes.

After adopting the above technical solution, not only may a separate signal control cable be used, but also the control signal loaded on the power line may be extracted and decoded, then data corresponding to the address of the communication chip may be extracted, and a driving signal that may be recognized by the LED lamp 103 may be output, reducing resource usage. At the same time, the lighting method of the LED lamp 103 may be determined according to the control signal, achieving various lighting effects, such as dynamic flashing, multi-color lighting, or alternating lighting. Moreover, by carrying the control signal on the power line of the cable structure 100, both signal transmission and power supply may work normally simultaneously, greatly simplifying the circuit structure of the data line. The design is ingenious, cost-effective, and practical.

In some embodiments, the power line 102 includes a positive line 1021 for supplying power to the light-emitting chip 1034. The input end of the communication chip 1033 is connected to the output end of the positive line 1021. The output end of the communication chip 1033 is connected to the light-emitting chip 1034 for controlling the light-emitting chip 1034 to emit light.

In some embodiments, the power line 102 further includes a negative line 1022. The voltage level of the negative line 1022 is lower than that of the positive line 1021. The LED lamp 103 is electrically connected to the positive line 1021 and the negative line 1022 through the conductive pin 1032.

In some embodiments, the positive line 1021 may be a positive power line, and the negative line 1022 may be a ground line or a negative power line. The communication chip 1033 is connected to the positive line 1021 through the conductive pin 1032 to extract the carrier wave on the positive line 1021, i.e., the oscillated data information, then decode the carrier wave and output a driving signal that may be recognized by the light-emitting chip 1034, to drive the operation of the LED lamp 103, so that the LED lamp 103 has corresponding effect changes.

In some embodiments, a plurality of accommodating holes are arranged between the positive line 1021 and the negative line 1022. The plurality of accommodating holes are arranged sequentially along the length direction of the positive line 1021 and the negative line 1022. The plurality of LED lamps 103 are correspondingly accommodated in the plurality of accommodating holes, so that the cable structure 100 may emit light during charging or data transmission. At the same time, the light emitted by the LED lamps 103 is consistent with the extending direction of the cable structure 100, ensuring that the brightness of the optical paths at both ends of the cable structure is consistent with that in the middle area. At the same time, the communication chip 1033 inside the LED lamp 103 may achieve various lighting effects for the LED lamp 103.

In some embodiments, the insulating base 1031 is provided with a groove structure 10311, namely a first conductive groove and a second conductive groove. The first conductive groove and the second conductive groove are symmetrically arranged on two sides of the insulating base 1031. The positive line 1021 and the negative line 1022 correspondingly pass through the first conductive groove and the second conductive groove. The positive line 1021 and the negative line 1022 are correspondingly connected to the conductive pin 1032 on the LED lamp 103 to realize the electrical connection between the communication chip 1033 and the light-emitting chip 1034 and the positive line 1021 and the negative line 1022.

In some embodiments, the conductive pin 1032 include a GND pin 10321 and a VDD pin 10322. The communication chip 1033 is arranged on the GND pin 10321 and is electrically connected to the GND pin 10321 and the VDD pin 10322. The light-emitting chip 1034 is arranged on the VDD pin 10322 and is electrically connected to the VDD pin 10322 and the communication chip 1034.

In some embodiments, the GND pin 10321 has a first die-bonding portion 10321a and a first soldering portion 10321b connected to 10321a. The VDD pin 10322 has a second die-bonding portion 10322a and a second soldering portion 10322b connected to the second die-bonding portion 10322a. The communication chip 1033 is fixed on the first die-bonding portion 10321a. The light-emitting chip 1034 is fixed on the second die-bonding portion 10322a. The first soldering portion 10321b is soldered to the positive line 1021. The second soldering portion 10322b is soldered to the negative line 1022. The protective adhesive 1035 faces the extending direction of the positive line 1021 and the negative line 1022.

In some embodiments, the second die-bonding portion 10321a has a first notch. The first die-bonding portion 10322a has a first connection surface and a second connection surface which are connected to each other and arranged at intervals. The first connection surface and the second connection surface are arranged in the first notch. The first connection surface is arranged on the outside of the first notch. The communication chip 1033 is fixed on the second connection surface. The communication chip 1033 is electrically connected to the first connection surface through bonding wires. The light-emitting chip 1034 is electrically connected to the communication chip 1033 and the second die-bonding portion 10322a through bonding wires. By adopting the above technical solution, the connection between the protective adhesive 1035 and the insulating base 1031 may be more stable, and the stress generated when the protective adhesive 1035 expands due to heat may be released.

In this embodiment, the light-emitting chip 1034 includes a blue chip, a red chip, and a green chip. The blue chip, red chip, and green chip are arranged at intervals on the second die-bonding portion 10322a. The blue chip and the green chip are electrically connected to the second die-bonding portion 10322a through bonding wires. The bottom of the red chip is directly electrically connected to the second die-bonding portion 10322a.

In the description of the present application, it should be noted that, the terms “install”, “connected”, and “connection” should be understood broadly. For example, it may be a fixed connection, a detachable connection, or an integral connection. It may be a mechanical connection or an electrical connection. It may be a direct connection or an indirect connection through an intermediate medium. It may be the internal communication between two elements or the interaction relationship between two elements. For those of ordinary skill in the art, the specific meanings of the above terms in the present application may be understood according to specific circumstances.

In the present application, that a first feature is “on” or “under” a second feature may include that the first and second features are in direct contact, or may include that the first and second features are not in direct contact but are in contact through additional features between them. Moreover, that a first feature is “on”, “above”, or “over” a second feature includes that the first feature is directly above or obliquely above the second feature, or indicates that the horizontal height of the first feature is higher than that of the second feature. That a first feature is “under”, “below”, or “beneath” a second feature includes that the first feature is directly below or obliquely below the second feature, or indicates that the horizontal height of the first feature is less than that of the second feature.

The above disclosure provides many different embodiments or examples for implementing different structures of the present application. In order to simplify the disclosure of the present application, components and settings of specific examples are described above. Of course, they are examples and are not intended to limit the present application. In addition, the present application may repeat reference numerals and/or reference letters in different examples. Such repetition is for the purpose of simplicity and clarity and does not indicate the relationship between the various discussed embodiments and/or settings. In addition, the present application provides examples of various specific processes and materials, but those of ordinary skill in the art may recognize the application of other processes and/or the use of other materials.

In the description of this specification, descriptions referring to the terms “one embodiment”, “some embodiments”, “illustrative embodiment”, “example”, “specific example”, or “some examples” mean that specific features, structures, materials, or characteristics described in connection with the embodiment or example are included in at least one embodiment or example of the present application. In this specification, the schematic representations of the above terms do not necessarily refer to the same embodiment or example. Moreover, the described specific features, structures, materials, or characteristics may be combined in any one or more embodiments or examples in a suitable manner.

What is claimed is:

1. A cable structure, comprising: a power line and a communication line;
wherein a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp comprises an insulating base, a communication chip, a light-emitting chip, and a conductive pin integrally embedded and molded with the insulating base; a protective adhesive is formed on the insulating base and covers the outside of the communication chip and the light-emitting chip; and
the communication chip and the light-emitting chip are arranged in the insulating base and are electrically connected to the power line through the conductive pin; the communication chip is configured to extract a control signal loaded on the power line and perform decoding work, and then extract data corresponding to an address of the communication chip, and output a driving signal that is recognized by the light-emitting chip.

2. The cable structure according to claim 1, wherein the power line comprises a positive line and a negative line;
the positive line is connected to a VDD pin of the communication chip; and
the negative line is connected to a GND pin of the communication chip.

3. The cable structure according to claim 2, wherein a plurality of accommodating holes are arranged between the positive line and the negative line;
the plurality of accommodating holes are arranged sequentially along a length direction of the positive line and the negative line; and
the plurality of LED lamps are correspondingly accommodated in the plurality of accommodating holes.

4. The cable structure according to claim 2, wherein the insulating base is provided with a first conductive groove and a second conductive groove;
the first conductive groove and the second conductive groove are respectively arranged on two sides of the insulating base; and
the positive line and the negative line correspondingly pass through the first conductive groove and the second conductive groove.

5. The cable structure according to claim 2, wherein the conductive pin comprises a GND pin and a VDD pin;
the communication chip is arranged on the GND pin and is electrically connected to the GND pin and the VDD pin; and
the light-emitting chip is arranged on the VDD pin and is electrically connected to the VDD pin and the communication chip.

6. The cable structure according to claim 5, wherein the GND pin has a first die-bonding portion and a first soldering portion;
the VDD pin has a second die-bonding portion and a second soldering portion;
the communication chip is fixed on the first die-bonding portion;
the light-emitting chip is fixed on the second die-bonding portion;
the first soldering portion is soldered to the positive line; and
the second soldering portion is soldered to the negative line.

7. The cable structure according to claim 6, wherein the second die-bonding portion has a first notch;
the first die-bonding portion has a first connection surface and a second connection surface which are connected to each other and arranged at intervals; and
the first connection surface and the second connection surface are arranged in the first notch.

8. The cable structure according to claim 1, wherein the cable structure further comprises a light-homogenizing tube;
the light-homogenizing tube is arranged on the outside of the power line and the LED lamps; and
the communication line is wound on the outside of the light-homogenizing tube and forms a light-transmitting hole.

9. The cable structure according to claim 8, wherein the communication line includes a plurality of data transmission lines; and
the plurality of data transmission lines are cross-woven with each other to form an entire outer layer of the light-homogenizing tube.

10. A cable structure, comprising: a power line and a communication line;
wherein a plurality of LED lamps are arranged on the power line at intervals; light-emitting directions of the plurality of LED lamps are the same as an extending direction of the power line;
the communication line is wrapped on the outside of the power line, the power line is wrapped on the outside of the communication line, or the power line and the communication line are arranged side by side;
the LED lamp comprises an insulating base, a communication chip, a light-emitting chip, and conductive pin integrally embedded and molded with the insulating base; a protective adhesive is formed on the insulating base and covers the outside of the light-emitting chip; and
the communication chip and the light-emitting chip are arranged in the insulating base and is electrically connected to the power line through the conductive pin.

11. The cable structure according to claim 10, wherein the cable structure further comprises a data transmission line; and
the data transmission line is connected to the communication chip through the conductive pin and is configured to drive the light-emitting chip to emit light.

12. The cable structure according to claim 10, wherein the cable structure further comprises a light-homogenizing tube;
the power line and/or the communication line are arranged inside the light-homogenizing tube; or
the power line, the communication line, and/or a data transmission line of the cable structure are arranged inside the light-homogenizing tube.

13. The cable structure according to claim 10, wherein the communication line and the power line are twisted together to form a wire bundle; and
an outer layer made of a light-homogenizing material is arranged on the outside of the wire bundle.

14. The cable structure according to claim 13, wherein the outer layer comprises a light-homogenizing tube;
the light-homogenizing tube is sleeved on the outside of the wire bundle; or
the light-homogenizing tube is coated on the outside of the wire bundle by an injection molding process.

15. The cable structure according to claim 13, wherein the outer layer comprises a braided sleeve; and
the braided sleeve is coated on the outside of the wire bundle.

16. The cable structure according to claim 13, wherein the cable structure further comprises a spacer fabric made of an opaque material; and
the spacer fabric is coated on the outside of the outer layer, light on the outer layer pass through gaps of the spacer fabric.

17. The cable structure according to claim 16, wherein the spacer fabric comprises a plurality of opaque braided lines; and
the plurality of braided lines are cross-woven with each other and are coated on the outside of the light-homogenizing tube.

18. The cable structure according to claim 10, wherein an outer layer made of a light-homogenizing material is arranged on the outside of the power line; and
the communication lines are cross-woven with each other and are coated on the outside of the outer layer.

19. A data line, comprising: a cable structure according to claim 10, and an adapter interface;
wherein the cable structure has an input end for connecting to an external host or an external power source, and an output end for transmitting data or supplying power to an electronic device;
a USB connector of the adapter interface is connected to the input end;
a charging plug of the adapter interface is connected to the output end;
when the data line transmits data or supplies power to the electronic device, the communication chip is configured to analyze and process the control signal transmitted by a driving module through power line carrier and generate the driving signal that is recognized by the light-emitting chip, to control operation of the LED lamps of the cable structure.

20. The data line according to claim 19, wherein the adapter interface comprises: an interface body and a circuit board;
a cavity structure is arranged on the interface body; and
the circuit board is accommodated in the cavity structure and is provided with a driving module for encoding a control signal, the control signal is transmitted externally through power line carrier, to control LED lamps of a cable structure connected to the interface body to emit light.
